(19) United States
(12) Patent Application Publication
(10) Pub. No.: US 2024/0393667 A1
(43) Pub. Date: Nov. 28, 2024

(54) PHOSPHOR, WAVELENGTH CONVERSION DEVICE, ILLUMINATION DEVICE, AND PROJECTOR

(71) Applicant: SEIKO EPSON CORPORATION, Tokyo (JP)

(72) Inventors: Kengo KANO, MATSUMOTO-SHI (JP); Soma TODA, MATSUMOTO-SHI (JP)

(21) Appl. No.: 18/673,566

(22) Filed: May 24, 2024

(30) Foreign Application Priority Data
May 24, 2023 (JP) 2023-085216

(51) Int. Cl. G03B 21/20

(52) U.S. Cl. CPC G03B 21/204

(57) ABSTRACT

A phosphor has a phosphor body including a phosphor phase formed of A₃B₅O₁₂:Ce having a garnet structure, a matrix phase having a refractive index higher than a refractive index of the phosphor phase, and a crystal phase formed of YAlO₃ having a perovskite structure. A content of the crystal phase is more than 0 vol % and is equal to or less than 7.0 vol % in a volume ratio with respect to the phosphor body. A is at least one selected from a group including Lu, Gd, Tb, Ga, and Y, and B is Al.

The present application is based on, and claims priority from JP Application Serial Number 2023-085216, filed May 24, 2023, the disclosure of which is hereby incorporated by reference herein in its entirety.

### BACKGROUND

### 1. Technical Field

The present disclosure relates to a phosphor, a wavelength conversion device, an illumination device, and a projector.

### 2. Related Art

In the related art, a ceramic composite is used as a wavelength conversion member used in a light source for a projector. JP-A-2012-062459 discloses a ceramic composite including an inorganic material having a matrix phase formed of a transparent ceramic such as Al₂O₃, MgAl₂O₄, or MgO, and a phosphor phase formed of YAG containing Ce.

However, in the ceramic composite disclosed in JP-A-2012-062459, although a thermal conductivity is improved by mixing and sintering of a high thermal conductive filler, it is difficult to sufficiently improve fluorescence extraction efficiency.

### SUMMARY

In order to solve the above problems, according to an aspect of the present disclosure, there is provided a phosphor including a phosphor body including a phosphor phase formed of A₃B₅O₁₂:Ce having a garnet structure, a matrix phase having a refractive index higher than a refractive index of the phosphor phase, and a crystal phase formed of YAlO₃ having a perovskite structure. A content of the crystal phase is more than 0 vol % and is equal to or less than 7.0 vol % in a volume ratio with respect to the phosphor body. A is at least one selected from a group including Lu, Gd, Tb, Ga, and Y, and B is Al.

According to another aspect of the present disclosure, there is provided a wavelength conversion device including a substrate, the phosphor according to the above aspect, provided on the substrate and configured to convert an incident excitation light into fluorescence, and a reflection layer provided at an opposite side to a light incident side of the phosphor and configured to reflect the excitation light and the fluorescence.

According to still another aspect of the present disclosure, there is provided a wavelength conversion device including a substrate, the phosphor according to the above aspect, provided on the substrate and configured to convert an incident excitation light into fluorescence, and an optical layer provided on a light incident side of the phosphor and configured to transmit the excitation light and reflect the fluorescence.

According to another aspect of the present disclosure, there is provided an illumination device including a light source emitting an excitation light, and the wavelength conversion device according to the above aspect on which the excitation light is incident.

According to yet another aspect of the present disclosure, there is provided a projector including the illumination device according to the above aspect, a light modulator modulating a light emitted from the illumination device, and a projection optical device projecting the light modulated by the light modulator.

### BRIEF DESCRIPTION OF THE DRAWINGS

FIG. 1 is a schematic configuration diagram showing a projector according to a first embodiment.

FIG. 2 is a schematic configuration diagram showing an illumination device.

FIG. 3 is a cross-sectional view showing a configuration of a wavelength conversion device.

FIG. 4 shows an emission spectrum in a phosphor.

FIG. 5 is an SEM image of the phosphor.

FIG. 6 is a schematic configuration diagram showing an illumination device according to a second embodiment.

### DESCRIPTION OF EMBODIMENTS

As below, embodiments of the present disclosure will be described in detail with reference to the drawings. In the drawings used in the following description, in order to facilitate understanding of features, a feature portion may be shown in an enlarged manner for convenience, and dimensional ratios or the like of the respective component elements are not necessarily the same as actual dimensional ratios.

### First Embodiment

Hereinafter, an embodiment of the present disclosure will be described.

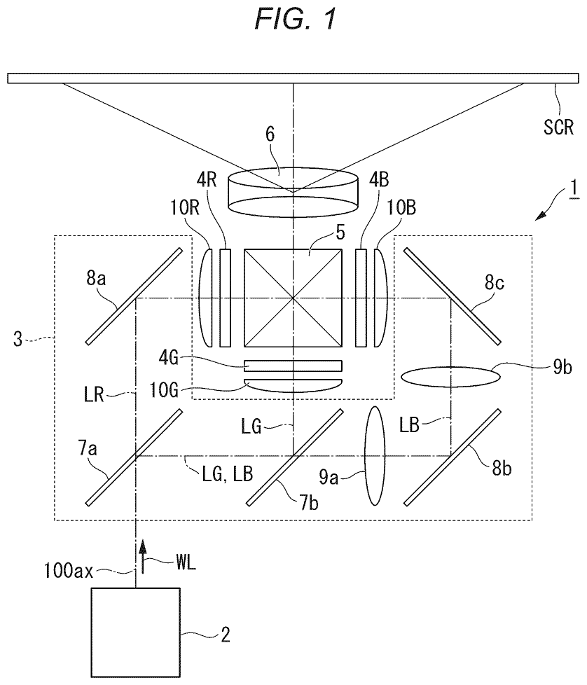

FIG. 1 is a schematic configuration diagram showing a projector according to a first embodiment.

As shown in FIG. 1, a projector 1 according to the embodiment is a projection-type image display device that displays an image on a screen SCR. The projector 1 includes an illumination device 2, a color separation system 3, a light modulator 4R, a light modulator 4G, a light modulator 4B, a combining system 5, and a projection optical device 6.

The illumination device 2 emits a white illumination light WL toward the color separation system 3. A configuration of the illumination device 2 will be described in detail later.

The color separation system 3 separates the illumination light WL emitted from the illumination device 2 into a red light LR, a green light LG, and a blue light LB. The color separation system 3 includes a first dichroic mirror 7a, a second dichroic mirror 7b, a first reflection mirror 8a, a second reflection mirror 8b, a third reflection mirror 8c, a first relay lens 9a, and a second relay lens 9b.

The first dichroic mirror 7a separates the illumination light WL from the illumination device 2 into the red light LR and a light including the green light LG and the blue light LB. The first dichroic mirror 7a transmits the red light LR and reflects the light including the green light LG and the blue light LB. On the other hand, the second dichroic mirror 7b reflects the green light LG and transmits the blue light LB. Accordingly, the second dichroic mirror 7b separates the light including the green light LG and the blue light LB into the green light LG and the blue light LB.

The first reflection mirror 8a is disposed in an optical path of the red light LR, and reflects the red light LR transmitted through the first dichroic mirror 7a toward the light modulator 4R. On the other hand, the second reflection mirror 8b and the third reflection mirror 8c are disposed in an optical path of the blue light LB, and guide the blue light LB transmitted through the second dichroic mirror 7b to the light modulator 4B. The green light LG is reflected from the second dichroic mirror 7b toward the light modulator 4G.

The first relay lens 9a is disposed between the second dichroic mirror 7b and the second reflection mirror 8b in the optical path of the blue light LB. The second relay lens 9b is disposed between the second reflection mirror 8b and the third reflection mirror 8c in the optical path of the blue light LB. The first relay lens 9a and the second relay lens 9b compensate for an optical loss of the blue light LB due to an optical path length of the blue light LB being longer than an optical path length of the red light LR or the green light LG.

The light modulator 4R modulates the red light LR according to image information to form an image light corresponding to the red light LR. The light modulator 4G modulates the green light LG according to image information to form an image light corresponding to the green light LG. The light modulator 4B modulates the blue light LB according to image information to form an image light corresponding to the blue light LB.

For example, a transmissive liquid crystal panel is used for each of the light modulator 4R, the light modulator 4G, and the light modulator 4B. A polarizer (not shown) is disposed at each of a light incident side and a light exiting side of the liquid crystal panel.

A field lens 10R is disposed at a light incident side of the light modulator 4R. The field lens 10R parallelizes the red light LR incident on the light modulator 4R. A field lens 10G is disposed at a light incident side of the light modulator 4G. The field lens 10G parallelizes the green light LG incident on the light modulator 4G. A field lens 10B is disposed at a light incident side of the light modulator 4B. The field lens 10B parallelizes the blue light LB incident on the light modulator 4B.

The image lights emitted from the light modulator 4R, the light modulator 4G, and the light modulator 4B enter the combining system 5. The combining system 5 combines the image lights respectively corresponding to the red light LR, the green light LG, and the blue light LB, and emits the combined image light toward the projection optical device 6. For example, a cross dichroic prism is used for the combining system 5.

The projection optical device 6 includes a plurality of projection lenses. The projection optical device 6 enlarges and projects the image light combined by the combining system 5 toward the screen SCR. Accordingly, an enlarged image is displayed on the screen SCR.

Hereinafter, a configuration of the illumination device 2 will be described.

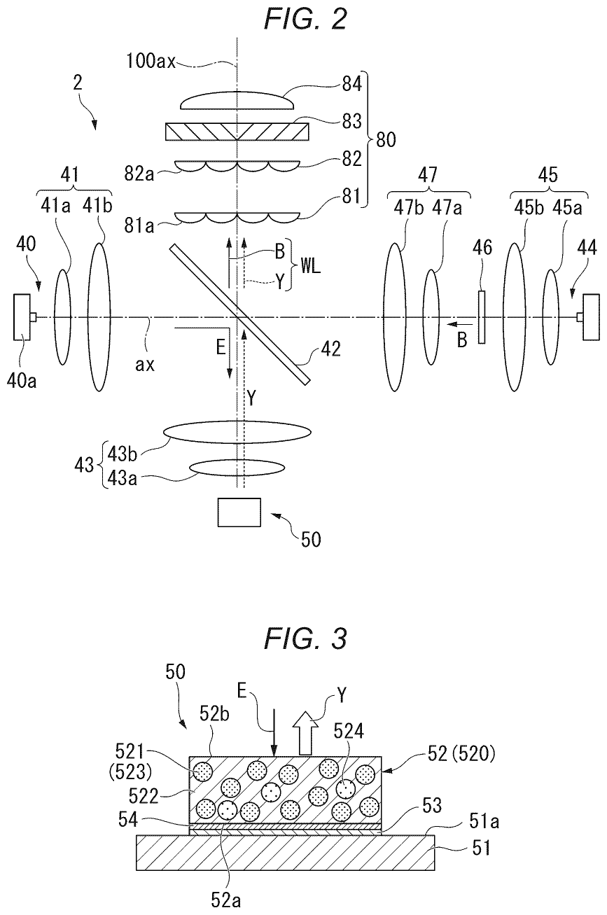

FIG. 2 is a schematic configuration diagram showing the illumination device 2 according to the embodiment.

As shown in FIG. 2, the illumination device 2 includes a first light source 40, a collimating system 41, a dichroic mirror 42, a first condensing system 43, a wavelength conversion device 50, a second light source 44, a second condensing system 45, a diffuser 46, and a collimating system 47.

The first light source 40 includes a plurality of semiconductor lasers 40a that emit a blue excitation light E of a laser beam. A peak of an emission intensity of the excitation light E is, for example, 445 nm. The plurality of semiconductor lasers 40a are arranged in an array manner in one plane orthogonal to an optical axis ax of the first light source 40. The semiconductor laser 40a may be a semiconductor laser that emits a blue light having a wavelength other than 445 nm, for example, 455 nm or 460 nm. The optical axis ax of the first light source 40 is orthogonal to an illumination optical axis 100ax of the illumination device 2.

The first light source 40 according to the embodiment corresponds to “light source” in the claims.

The collimating system 41 includes a first lens 41a and a second lens 41b. The collimating system 41 substantially parallelizes the light emitted from the first light source 40. Each of the first lens 41a and the second lens 41b is formed using a convex lens.

The dichroic mirror 42 is disposed in an optical path from the collimating system 41 to the first condensing system 43 in a direction intersecting each of the optical axis ax of the first light source 40 and the illumination optical axis 100ax at an angle of 45°. The dichroic mirror 42 reflects a blue light component and transmits a red light component and a green light component. Therefore, the dichroic mirror 42 reflects the excitation light E and the blue light B and transmits yellow fluorescence Y.

The first condensing system 43 condenses the excitation light E transmitted through the dichroic mirror 42 and causes the excitation light E to enter the wavelength conversion device 50, and substantially parallelizes the fluorescence Y emitted from the wavelength conversion device 50. The first condensing system 43 includes a first lens 43a and a second lens 43b. Each of the first lens 43a and the second lens 43b is formed using a convex lens.

The second light source 44 is formed using a semiconductor laser having a wavelength band same as a wavelength band of the first light source 40. The second light source 44 may be formed using one semiconductor laser, or may be formed using a plurality of semiconductor lasers. In addition, the second light source 44 may be formed using a semiconductor laser having a wavelength band different from that of the semiconductor laser of the first light source 40.

The second condensing system 45 includes a first lens 45a and a second lens 45b. The second condensing system 45 condenses the blue light B emitted from the second light source 44 on a diffusion surface of the diffuser 46 or near the diffusion surface. Each of the first lens 45a and the second lens 45b is formed using a convex lens.

The diffuser 46 diffuses the blue light B emitted from the second light source 44, and generates the blue light B having a light distribution close to a light distribution of the fluorescence Y emitted from the wavelength conversion device 50. As the diffuser 46, for example, a ground glass of an optical glass can be used.

The collimating system 47 includes a first lens 47a and a second lens 47b. The collimating system 47 substantially parallelizes the light emitted from the diffuser 46. Each of the first lens 47a and the second lens 47b is formed using a convex lens.

The blue light B emitted from the second light source 44 is reflected by the dichroic mirror 42, and is combined with the fluorescence Y emitted from the wavelength conversion device 50 and transmitted through the dichroic mirror 42 to generate the white illumination light WL. The illumination light WL enters a uniform illumination system 80.

The uniform illumination system 80 includes a first lens array 81, a second lens array 82, a polarization conversion element 83, and a superimposing lens 84.

The first lens array 81 includes a plurality of first lenses 81a for dividing the illumination light WL from the illumination device 2 into a plurality of partial luminous fluxes. The plurality of first lenses 81a are arranged in a matrix form in a plane orthogonal to the illumination optical axis 100ax.

The second lens array 82 includes a plurality of second lenses 82a corresponding to the plurality of first lenses 81a of the first lens array 81. The plurality of second lenses 82a are arranged in a matrix form in the plane orthogonal to the illumination optical axis 100ax.

The second lens array 82, together with the superimposing lens 84, forms images of the respective first lenses 81a of the first lens array 81 in the vicinity of image formation areas of the light modulator 4R, the light modulator 4G, and the light modulator 4B.

The polarization conversion element 83 converts the light emitted from the second lens array 82 into one linearly polarized light. The polarization conversion element 83 includes, for example, a polarization separation layer and a retardation film (not shown).

The superimposing lens 84 condenses the respective partial luminous fluxes emitted from the polarization conversion element 83 and superimposes the luminous fluxes in the vicinity of the image formation areas of the light modulator 4R, the light modulator 4G, and the light modulator 4B.

Next, a configuration of the wavelength conversion device 50 will be described.

FIG. 3 is a cross-sectional view showing the configuration of the wavelength conversion device 50. FIG. 3 corresponds to a cross section of the wavelength conversion device 50 cut along a plane containing the illumination optical axis 100ax in FIG. 2.

As shown in FIG. 3, the wavelength conversion device 50 includes a substrate 51, a phosphor 52, a bonding layer 53, and a reflection layer 54. The wavelength conversion device 50 according to the embodiment is a fixed type wavelength conversion device in which an incident position of the excitation light E on the phosphor 52 does not change over time.

The substrate 51 supports the reflection layer 54 and the phosphor 52 through the bonding layer 53. The substrate 51 is formed of, for example, a metal material having a high thermal conductivity, such as aluminum or copper. The bonding layer 53 is formed of, for example, a bonding material having a high thermal conductivity, such as a nanosilver paste. The bonding layer 53 bonds a first surface 51a as a surface of the substrate 51, and the phosphor 52.

The phosphor 52 includes a rear surface 52a facing the substrate 51 and a front surface 52b opposite to the rear surface 52a. The phosphor 52 emits the fluorescence Y obtained by wavelength-conversion of the excitation light E incident from the front surface 52b from the front surface 52b.

The reflection layer 54 is provided to face the rear surface 52a of the phosphor 52 with the bonding layer 53 in between. That is, the reflection layer 54 is provided between the substrate 51 and the rear surface 52a of the phosphor 52. The reflection layer 54 is formed of a metal film such as silver having a high optical reflectance, a dielectric multilayer film, or a combination of these films. The reflection layer 54 reflects the fluorescence Y traveling toward an opposite side to the light incident side (the rear surface 52a side) within the phosphor 52 toward the light incident side (the front surface 52b side). The reflection layer 54 may reflect a part of the excitation light E to the light incident side (the front surface 52b side), and the excitation light E reflected by the reflection layer 54 is used to excite the fluorescence Y.

The wavelength conversion device 50 according to the embodiment functions as a reflective wavelength conversion device that emits the fluorescence Y from the front surface 52b of the phosphor 52 on which the excitation light E is incident.

It is generally known that when the temperature of the phosphor increases, the light emission efficiency of fluorescence decreases. In order to enhance the conversion efficiency of fluorescence in the phosphor, it is effective to enhance heat dissipation.

The inventors focused on enhancing the thermal conductivity of a phosphor by mixing and sintering of a YAG:Ce phosphor that is widely used as a phosphor and a high thermal conductive filler formed of AlN. In general, a sintered body of a phosphor including a phosphor phase formed of YAG:Ce and a matrix phase formed of AlN is formed by mixing and sintering of Al₂O₃ (alumina), Y₂O₃ (yttria), and CeO₂ (cerium oxide) which are raw-material powders and AlN powder which is a binder material.

However, when YAG:Ce and AlN are simply sintered, crystal defects of AlN are generated or oxynitride-based impurities such as AlON are generated, which makes it difficult to sufficiently improve the thermal conductivity of the phosphor and a decrease in fluorescent emission efficiency reduces an extraction amount of fluorescence. That is, only by simple sintering of YAG:Ce and AlN, the external quantum yield decreases and the extraction amount of fluorescence decreases. The external quantum yield refers to a value (unit: %) obtained by division of the total light emission amount of the fluorescence by the total light amount of the excitation light.

As a result of earnest studies, the inventors have found that, when a fluorescence emission element including a sintered body containing a crystal phase formed of YAG:Ce and a matrix phase formed of AlN is produced, the mixing of the raw-material powder of YAG:Ce is adjusted so that a predetermined amount of crystal phase is expressed in the phosphor phase, and thereby, the thermal conductivity of the phosphor is enhanced and the external quantum yield (extraction amount) of fluorescence is increased. Then, the inventors accomplished the configuration of the phosphor 52 according to the embodiment.

Specifically, the phosphor 52 of the embodiment includes a phosphor body 520 including a phosphor phase 521, a matrix phase 522, a crystal phase 523, and another phosphor phase 524.

In the phosphor 52, the phosphor phase 521 contains phosphor particles formed of A₃B₅O₁₂:Ce having a garnet structure. In the phosphor phase 521 according to the embodiment, A is Y (yttrium) and B is AL (aluminum). That is, the phosphor phase 521 according to the embodiment contains phosphor particles formed of yttrium aluminum garnet (YAG (Y₃Al₅O₁₂):Ce) to which cerium (Ce) is added as an activator.

The matrix phase 522 is a transparent ceramic that functions as a binder for binding a plurality of phosphor particles forming the phosphor phase 521 and that transmits fluorescence emitted by the phosphor phase 521. The matrix phase 522 according to the embodiment is formed of aluminum nitride (AlN). The matrix phase 522 has a refractive index (2.2) higher than a refractive index of YAG:Ce (1.8) forming the phosphor phase 521.

A thermal conductivity of AlN forming the matrix phase 522 is about 285 W/m·K, and a thermal conductivity of YAG:Ce forming the phosphor phase 521 is about 9 W/m·K. That is, the matrix phase 522 has the thermal conductivity sufficiently higher than the thermal conductivity of the phosphor phase 521.

The thermal conductivity of the matrix phase 522 according to the embodiment is sufficiently higher than the thermal conductivity of Al₂O₃ (alumina) (about 30 W/m·K), which is generally used as a matrix phase of a ceramic phosphor. Therefore, the phosphor 52 according to the embodiment has excellent thermal conductivity and excellent heat dissipation as compared with a phosphor in the related art that uses Al₂O₃ as the matrix phase.

In the phosphor 52 of the embodiment, the crystal phase 523 is provided in the phosphor phase 521. It is difficult to determine that the phosphor phase 521 includes the crystal phase 523 based on an image or the like, however, that can be determined by using, for example, an X-ray diffraction method (XRD).

The crystal phase 523 includes YAlO₃ (hereinafter, YAP) having a perovskite structure. In the phosphor 52 of the embodiment, the content of the crystal phase 523 is more than 0 vol % and 7.0 vol % or less in a volume ratio with respect to the phosphor body 520.

The other phosphor phase 524 includes phosphor particles formed of AlN:Ce. The other phosphor phase 524 is generated when the phosphor phase 521 and the matrix phase 522 are sintered.

Here, an emission spectrum of the phosphor 52 of the embodiment will be described.

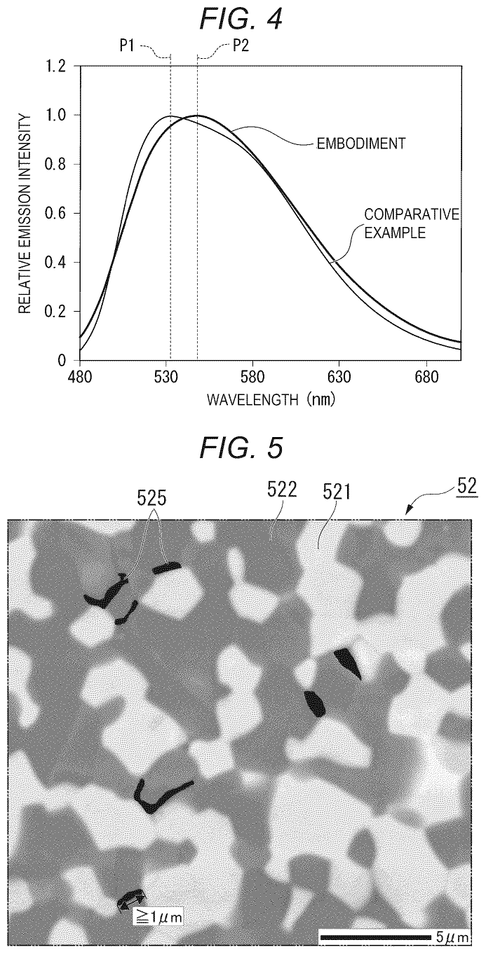

The thick solid line in FIG. 4 indicates the light emission spectrum in the phosphor 52 of the embodiment, and the thin solid line in FIG. 4 indicates the light emission spectrum in a phosphor of a comparative example. The difference between the phosphor of the comparative example and the phosphor 52 of the embodiment is in the presence or absence of the other phosphor phase 524 formed of AlN:Ce. In FIG. 4, the horizontal axis represents wavelength, and the vertical axis represents relative emission intensity.

As shown in FIG. 4, an emission peak wavelength P1 of the spectrum in the phosphor 52 of the embodiment is higher than an emission peak wavelength P2 of the spectrum in the phosphor of the comparative example. That is, according to the phosphor 52 of the embodiment, the emission peak wavelength can be shifted to the longer wavelength side by inclusion of the other phosphor phase 524 formed of AlN:Ce.

Therefore, according to the phosphor 52 of the embodiment, the color rendering property of the emitted fluorescence Y can be further improved by shifting of the peak wavelength to the longer wavelength side.

The phosphor 52 of the embodiment is manufactured, when YAG:Ce and AlN are sintered, by mixing and sintering of Y₂O₃ at a mass ratio of 56% or more and CeO₂ at a mass ratio of 0.5% or more of Al₂O₃, Y₂O₃, and CeO₂ as YAG raw-material powders, for example. As described above, in the manufacturing process of the phosphor 52 of the embodiment, a predetermined amount of YAP can be expressed in the phosphor phase 521 of the phosphor 52 by addition of excessive Y₂O₃.

In addition, in the case of the phosphor 52 of the embodiment, Y₂O₃ functions as a sintering additive during sintering of the phosphor body 520, and thus the phosphor body 520 forming the phosphor 52 includes a ceramic composite of a sintered body having a dense crystal structure. Accordingly, the phosphor 52 of the embodiment has the excellent thermal conductivity and the external quantum yield of the fluorescence Y can be enhanced.

The phosphor 52 of the embodiment includes a by-product different from the phosphor phase 521, the matrix phase 522, the crystal phase 523, and the other phosphor phase 524. The by-product of the embodiment is AlON which is an oxynitride impurity produced when the materials of the phosphor 52 are mixed and sintered.

In the phosphor 52 of the embodiment, the state in which the YAP is expressed within the phosphor phase 521 as described above refers to a progress of the sintering of the phosphor body 520 in good condition with suppressed production of by-products as impurities.

Therefore, in the phosphor 52 of the embodiment, the content of the by-product (AlON) is less than 1.0 vol % in a volume ratio with respect to the phosphor body 520. As described above, according to the phosphor 52 of the embodiment, the amount of by-products is smaller and the absorption of the fluorescence Y by the by-product and the heat generation caused by the absorption of the fluorescence Y is suppressed, and thereby, the conversion efficiency of the fluorescence can be enhanced and the bright fluorescence Y can be generated.

Here, when the content of the by-product (AlON) to be the impurity is smaller, the sintering of the phosphor body 520 is well progressed, and thus the generation of crystal defect of AlN forming the matrix phase 522 is also suppressed. Therefore, the content of the impurity caused by the AlN crystal defect in the phosphor body 520 is very small as in the case of the by-product. It is known that an emission peak wavelength of a phosphor light emitting element containing AlN having a high crystal defect rate is 610 nm.

On the other hand, in the phosphor 52 of the embodiment, the content of the by-product is smaller as described above, and the amount of impurity due to the crystal defect of AlN is smaller. Therefore, the emission peak wavelength of the phosphor body 520 in the phosphor 52 of the embodiment is less than 610 nm.

FIG. 5 shows a main part configuration of the phosphor 52 according to the embodiment. FIG. 5 is an image obtained by imaging of the phosphor 52 using an SEM (scanning electron microscope). The imaging range of the image shown in FIG. 5 is 400 μm².

In the phosphor 52 of the embodiment, the number of voids contained in the phosphor body 520 is smaller. Specifically, as shown in FIG. 5, in the sectional view of the phosphor body 520, the number of voids 525 of 1.0 μm or more contained within the imaging area of 400 μm² is nine or less. For example, the size of the void 525 is defined based on the length of the void 525 in the major axis direction in an image obtained in observation of a cross section of 400 μm² by microscopy.

In the phosphor 52 of the embodiment, since the number of voids 525 in the phosphor body 520 is smaller, the strength and the thermal conductivity in the phosphor body 520 can be further enhanced. Accordingly, the reliability of the phosphor 52 can be further enhanced.

As described above, the phosphor 52 of the embodiment includes the phosphor body 520 containing the phosphor phase 521 formed of YAG (Y₃Al₅O₁₂):Ce having the garnet structure, the matrix phase 522 formed of AlN having the refractive index higher than the refractive index of the phosphor phase 521, and the crystal phase 523 formed of YAlO₃ having the perovskite structure. The content of the crystal phase 523 is more than 0 vol % and 7.0 vol % or less in the volume ratio with respect to the phosphor body 520. Hereinafter, in the specification, the content of the crystal phase 523 is referred to as “YAP amount”.

According to the phosphor 52 of the embodiment, since the YAP amount contained in the phosphor body 520 is more than 0 vol % and 7.0 vol % or less, the phosphor is sintered with excessive addition of Y₂O₃ functioning as the sintering additive. Since the phosphor 52 is sintered with the content of the large amount of Y₂O₃ functioning as the sintering additive, the phosphor includes the phosphor body 520 of the ceramic composite having the dense crystal structure.

In addition, since the phosphor 52 of the embodiment includes the matrix phase 522 formed of AlN having the high thermal conductivity, a decrease in fluorescence conversion efficiency due to a temperature rise can be suppressed by efficient release of heat caused by fluorescence emission. As a result, the excitation light E is efficiently absorbed by the phosphor phase 521 and the light emission efficiency of the fluorescence Y is enhanced, and thereby, the bright fluorescence Y can be generated.

According to the phosphor 52 of the embodiment, the fluorescence Y having the brightness acceptable in practical use as the illumination light for the projector can be emitted from the phosphor 52 by enhancement of the external quantum yield of the fluorescence Y to 55% or more.

The wavelength conversion device 50 according to the embodiment includes the substrate 51, the phosphor 52 that is provided on the substrate 51 and converts the incident excitation light E into the fluorescence, and the reflection layer 54 that is provided at the opposite side to the light incident side of the phosphor 52.

According to the wavelength conversion device 50 of the embodiment, the reflective wavelength conversion device that efficiently extracts the bright fluorescence Y can be provided.

The illumination device 2 according to the embodiment includes the first light source 40 that emits the excitation light E and the wavelength conversion device 50 on which the excitation light E is incident.

According to the illumination device 2 of the embodiment, the illumination device that has excellent wavelength conversion efficiency and emits the bright illumination light WL can be provided.

The projector 1 according to the embodiment includes the illumination device 2, the light modulators 4R, 4G, and 4B that modulate the light emitted from the illumination device 2, and the projection optical device 6 that projects the light modulated by the light modulators 4R, 4G, and 4B.

According to the projector 1 of the embodiment, the projector having excellent display quality and high efficiency can be provided.

### Second Embodiment

Hereinafter, a projector according to a second embodiment will be described.

A basic configuration of the projector according to the second embodiment is the same as that of the first embodiment, and a configuration of the illumination device is different from that of the first embodiment. Therefore, the configuration of the illumination device will be described below.

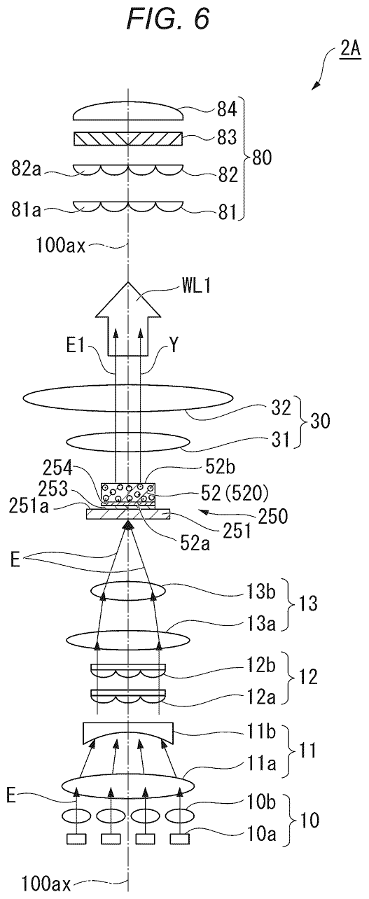

FIG. 6 is a schematic configuration diagram showing an illumination device 2A according to the second embodiment.

In FIG. 6, the component elements common to those in the drawings used in the above embodiment have the same signs, and the description thereof is omitted.

As shown in FIG. 6, the illumination device 2A includes an excitation light source unit 10, an afocal system 11, a homogenizer system 12, a condensing system 13, a wavelength conversion device 250, a pickup system 30, and the uniform illumination system 80.

The excitation light source unit 10 includes a plurality of semiconductor lasers 10a that emit the blue excitation lights E as laser beams, and a plurality of collimator lenses 10b. The plurality of semiconductor lasers 10a are arranged in an array manner in a plane orthogonal to the illumination optical axis 100ax. The collimator lenses 10b are arranged in an array manner in the plane orthogonal to the illumination optical axis 100ax so as to correspond to the respective semiconductor lasers 10a. The collimator lens 10b converts the excitation light E emitted from the semiconductor laser 10a corresponding to the collimator lens 10b into a parallel light.

The excitation light source unit 10 according to the embodiment corresponds to “light source” in the claims.

The afocal system 11 includes, for example, a convex lens 11a and a concave lens 11b. The afocal system 11 reduces a luminous flux diameter of the excitation light E including a parallel luminous flux emitted from the excitation light source unit 10.

The homogenizer system 12 includes, for example, a first multi-lens array 12a and a second multi-lens array 12b. The homogenizer system 12 makes a light intensity distribution of the excitation light uniform on the phosphor 52 of the wavelength conversion device 250, that is, a so-called top hat distribution. The homogenizer system 12, together with the condensing system 13, superimposes a plurality of small luminous fluxes emitted from a plurality of lenses of the first multi-lens array 12a and the second multi-lens array 12b on the phosphor 52 of the wavelength conversion device 250. Accordingly, the light intensity distribution of the excitation light E emitted to the phosphor 52 is made uniform.

The condensing system 13 includes, for example, a first lens 13a and a second lens 13b. In the embodiment, each of the first lens 13a and the second lens 13b is formed using a convex lens. The condensing system 13 is disposed in an optical path from the homogenizer system 12 to the wavelength conversion device 250, condenses the excitation light E, and causes the excitation light E to enter the phosphor 52 of the wavelength conversion device 250.

The wavelength conversion device 250 according to the embodiment includes a substrate 251, the phosphor 52, a bonding layer 253, and an optical layer 254. The wavelength conversion device 250 according to the embodiment is a fixed-type wavelength conversion device in which an incident position of the excitation light E on the phosphor 52 does not change over time.

The substrate 251 supports the optical layer 254 and the phosphor 52 through the bonding layer 253. The substrate 251 is formed of, for example, a transparent material such as a glass or a plastic. The bonding layer 253 according to the embodiment is formed of, for example, a material having optical transparency, such as epoxy. The bonding layer 253 bonds a first surface 251a, which is a front surface of the substrate 251, and the phosphor 52.

In the phosphor 52 according to the embodiment, the excitation light E enters from the rear surface 52a facing the substrate 251, and the fluorescence Y is emitted from the front surface 52b. In the wavelength conversion device 250 according to the embodiment, the phosphor 52 transmits and emits not only the fluorescence Y but also a part of an excitation light E1 whose wavelength is not converted. Accordingly, a white illumination light WL1 is emitted from the phosphor 52.

The optical layer 254 is provided on the rear surface 52a at the light incident side of the phosphor 52. The optical layer 254 includes a dichroic mirror that transmits the excitation light E and reflects the fluorescence Y.

The wavelength conversion device 250 according to the embodiment functions as a transmissive wavelength conversion device that emits the illumination light WL1 containing the fluorescence Y from the front surface 52b opposite to the rear surface 52a of the phosphor 52 on which the excitation light E is incident.

The pickup system 30 includes, for example, a first collimating lens 31 and a second collimating lens 32. The pickup system 30 is a parallelizing system for substantially parallelizing the light emitted from the phosphor 52 of the wavelength conversion device 250. Each of the first collimating lens 31 and the second collimating lens 32 is formed using a convex lens. The light parallelized by the pickup system 30 is incident on the uniform illumination system 80.

### Effects of Second Embodiment

According to the embodiment, the transmissive wavelength conversion device 250 that generates the bright fluorescence Y can be realized by using the phosphor 52 that can increase an amount of extracted fluorescence Y. In addition, in the illumination device 2A according to the embodiment as well, the transmissive wavelength conversion device 250 is provided, and thereby, the effect same as that of the first embodiment in which the wavelength conversion efficiency is excellent and the bright illumination light WL1 can be emitted can be obtained.

The technical scope of the present disclosure is not limited to the above embodiments, and various modifications can be made without departing from the gist of the present disclosure.

Specific descriptions of shapes, numbers, arrangements, materials, manufacturing methods, and the like of the respective component elements of the phosphor, the wavelength conversion device, the illumination device, and the projector described in the above embodiments are not limited to those of the above embodiments, and can be appropriately changed.

In the above embodiments, YAG containing Ce is taken as an example of the phosphor phase 521, and the present disclosure is also applicable to a case of using a phosphor phase containing Ce in at least one of Lu₃Al₅O₁₂, Tb₃Al₅O₁₂, Ga₃Al₅O₁₂, and Gd₃Al₅O₁₂. That is, in addition to the case of using Y (yttrium), the present disclosure is also applicable to a case in which A in the garnet structure (A₃B₅O₁₂:Ce) is replaced with any of Lu (lutetium), Gd (gallium), Tb (terbium), and Ga (gallium) providing emission characteristics similar to those of Y.

Hereinafter, a summary of the disclosure will be appended.

### Appendix 1

A phosphor includes a phosphor body including a phosphor phase formed of A₃B₅O₁₂:Ce having a garnet structure, a matrix phase having a refractive index higher than a refractive index of the phosphor phase, and a crystal phase formed of YAlO₃ having a perovskite structure, wherein a content of the crystal phase is more than 0 vol % and 7.0 vol % or less in a volume ratio with respect to the phosphor body.

A is at least one selected from a group including Lu, Gd, Tb, Ga, and Y, and B is Al.

According to the phosphor having the configuration, the phosphor includes the phosphor body that is sintered with a large amount of a sintering additive so as to contain the crystal phase whose content is more than 0 vol % and 7.0 vol % or less. Since the phosphor having the configuration includes a ceramic composite of a sintered body having a dense crystal structure, the thermal conductivity can be excellent and the external quantum yield of fluorescence can be enhanced. In addition, since the thermal conductivity is excellent, a decrease in fluorescence conversion efficiency due to a temperature rise can be suppressed by efficient release of heat caused by fluorescence emission.

Therefore, the phosphor having the configuration can efficiently generate bright fluorescence.

### Appendix 2

In the phosphor according to Appendix 1, A is Y.

According to the configuration, the phosphor that efficiently generates bright fluorescence containing the phosphor phase formed of YAG (Y₃Al₅O₁₂):Ce can be realized.

### Appendix 3

In the phosphor according to Appendix 1 or Appendix 2, the matrix phase is AlN.

According to the configuration, since the phosphor includes the matrix phase formed of AlN having a high thermal conductivity, a decrease in fluorescence conversion efficiency due to a temperature rise may be suppressed by efficient release of heat caused by fluorescence emission.

### Appendix 4

In the phosphor according to Appendix 3, the phosphor body further includes another phosphor phase formed of AlN:Ce.

According to the configuration, the phosphor body includes the other phosphor phase formed of AlN:Ce, and thereby, the emission peak wavelength of the phosphor body can be shifted to the longer wavelength side. Accordingly, the color rendering properties of the emitted fluorescence can be further enhanced.

### Appendix 5

In the phosphor according to any one of Appendix 1 to Appendix 4, a number of voids of 1.0 μm or more contained within an area of 400 μm² in a cross-sectional view of the phosphor body is nine or less.

According to the configuration, since the voids contained in the phosphor body are reduced, the strength and the thermal conductivity in the phosphor body can be further enhanced.

### Appendix 6

In the phosphor according to any one of Appendix 1 to Appendix 5, the phosphor body includes a by-product different from the phosphor phase, the matrix phase, and the crystal phase, and a content of the by-product is less than 1.0 vol % in a volume ratio with respect to the phosphor body.

According to the configuration, the content of the by-product in the phosphor body is suppressed to less than 1.0 vol %, and thereby, the phosphor having a high thermal conductivity and excellent fluorescence extraction efficiency can be provided.

### Appendix 7

In the phosphor according to any one of Appendix 1 to Appendix 6, an emission peak wavelength of the phosphor body is less than 610 nm.

According to the configuration, since the emission peak wavelength of the phosphor body is less than 610 nm, the phosphor in which the content of by-products is small and impurities caused by crystal defects are small can be provided.

### Appendix 8

A wavelength conversion device includes a substrate, the phosphor according to any one of Appendix 1 to Appendix 7 provided on the substrate and converting an incident excitation light into fluorescence, and a reflection layer provided at an opposite side to a light incident side of the phosphor.

According to the wavelength conversion device having the configuration, the reflective wavelength conversion device that efficiently extracts bright fluorescence Y can be provided.

### Appendix 9

A wavelength conversion device includes a substrate, the phosphor according to any one of Appendix 1 to Appendix 7 provided on the substrate and converting an incident excitation light into fluorescence, and an optical layer provided on a light incident side of the phosphor and transmitting the excitation light and reflecting the fluorescence.

According to the wavelength conversion device having the configuration, the transmissive wavelength conversion device that efficiently extracts bright fluorescence can be provided.

### Appendix 10

An illumination device includes a light source emitting the excitation light, and the wavelength conversion device according to Appendix 8 or Appendix 9, on which the excitation light is incident.

According to the illumination device having the configuration, the illumination device that has excellent wavelength conversion efficiency and emits a bright illumination light can be provided.

### Appendix 11

A projector includes the illumination device according to Appendix 10, a light modulator modulating a light emitted from the illumination device, and a projection optical device projecting the light modulated by the light modulator.

According to the projector having the configuration, the projector having excellent display quality and high efficiency can be provided.

### EXAMPLES

Hereinafter, the present disclosure will be described in more detail with reference to Examples, and the present disclosure is not limited to Examples.

### Example 1

First, the amounts of Al₂O₃, Y₂O₃, and CeO₂, which are YAG raw-material powders, were adjusted so that the YAP content was 0.1 vol %, and YAG:Ce and AlN were sintered to produce a phosphor of Example 1.

### Example 2

A phosphor of Example 2 was manufactured in the same process as in Example 1 except that the amounts of Al₂O₃, Y₂O₃, and CeO₂ as YAG raw-material powders were adjusted so that the YAP content was 0.3 vol %.

### Example 3

A phosphor of Example 3 was manufactured in the same process as in Example 1 except that the amounts of Al₂O₃, Y₂O₃, and CeO₂ as YAG raw-material powders were adjusted so that the YAP content was 0.7 vol %.

### Example 4

A phosphor of Example 4 was manufactured in the same process as in Example 1 except that the amounts of Al₂O₃, Y₂O₃, and CeO₂ as YAG raw-material powders were adjusted so that the YAP content was 1.1 vol %.

### Example 5

A phosphor of Example 5 was manufactured in the same process as in Example 1, except that the amounts of Al₂O₃, Y₂O₃, and CeO₂ as YAG raw-material powders were adjusted so that the YAP content was 1.9 vol %.

### Example 6

A phosphor of Example 6 was manufactured in the same process as in Example 1 except that the amounts of Al₂O₃, Y₂O₃, and CeO₂ as YAG raw-material powders were adjusted so that the YAP content was 4.6 vol %.

### Example 7

A phosphor of Example 7 was manufactured in the same process as in Example 1 except that the amounts of Al₂O₃, Y₂O₃, and CeO₂ as YAG raw-material powders were adjusted so that the YAP content was 7.0 vol %.

### Comparative Example 1

A phosphor of Comparative Example 1 was manufactured in the same process as in Example 1 except that the YAG raw-material powders were adjusted so that the YAP content was 0 vol %.

### Comparative Example 2

A phosphor of Comparative Example 2 was manufactured in the same process as in Example 1 except that the YAG raw-material powders were adjusted so that the YAP content was 7.2 vol %.

### Comparative Example 3

A phosphor of Comparative Example 3 was manufactured in the same process as in Example 1 except that the YAG raw-material powders were adjusted so that the YAP content was 8.0 vol %.

### Comparative Example 4

A phosphor of Comparative Example 4 was manufactured in the same process as in Example 1 except that the YAG raw-material powders were adjusted so that the YAP content was 9.1 vol %.

### Comparative Example 5

A phosphor of Comparative Example 5 was manufactured in the same process as in Example 1 except that the YAG raw-material powders were adjusted so that the YAP content was 10.0 vol %.

### Evaluation of Examples and Comparative Examples

In each of Examples and Comparative Examples described above, the number of voids (unit: piece), the thermal conductivity (unit: W/m·K), and the external quantum yield (unit: %) were checked as described below, and a phosphor having a higher external quantum yield and a higher thermal conductivity was determined as a phosphor having higher light utilization efficiency. Determination results are shown in Table 1. The number and size of voids were defined based on, for example, the length in the major axis direction of an image obtained in observation of a cross-section of 400 μm² by microscopy. The thermal conductivity is a value based on the measurement result at room temperature.

In Table 1, samples with thermal conductivities at 20% or more were evaluated as A (acceptable), and samples with thermal conductivities at less than 20% were evaluated as B (unacceptable). In addition, in Table 1, samples with external quantum yields at 55% or more were evaluated as A (acceptable), and samples with external quantum yields at less than 55% were evaluated as B (unacceptable).

Further, as overall evaluations, samples whose evaluation items of the thermal conductivity and the external quantum yield were both A were rated A (acceptable), and samples whose evaluation item of at least one of the thermal conductivity and the external quantum yield was B were rated B (unacceptable). In Table 1, the content (vol %) of YAP relative to the entire phosphor was the YAG amount.

TABLE 1

| | YAP | | Number | Thermal |
|---|---|---|---|---|
| | amount | Emission peak | of voids | conductivity |
| | (vol %) | wavelength (nm) | (pieces) | (W/m · K) |
| Comparative | 0 | 534.0 | 16 | 14.3 |
| Example 1 | | | | |
| Example 1 | 0.1 | 534.0 | 9 | 40.9 |
| Example 2 | 0.3 | 533.2 | 8 | 40.7 |
| Example 3 | 0.7 | 530.0 | 8 | 46.1 |
| Example 4 | 1.1 | 533.8 | 7 | 41.4 |
| Example 5 | 1.9 | 533.2 | 5 | 59.2 |
| Example 6 | 4.6 | 532.8 | 7 | 43.0 |
| Example 7 | 7.0 | 535.0 | 6 | 40.1 |
| Comparative | 7.2 | 540.0 | 9 | 36.7 |
| Example 2 | | | | |
| Comparative | 8.0 | 541.0 | 4 | 38.0 |
| Example 3 | | | | |
| Comparative | 9.1 | 550.0 | 5 | 31.6 |
| Example 4 | | | | |
| Comparative | 10.0 | 565.0 | 8 | 30.8 |
| Example 5 | | | | |

| | External | Evaluation | Evaluation | |
|---|---|---|---|---|
| | quantum | of thermal | of external | |
| | yield (%) | conductivity | quantum yield | Determination |
| Comparative | 46.8 | B | B | B |
| Example 1 | | | | |
| Example 1 | 65.6 | A | A | A |
| Example 2 | 64.9 | A | A | A |
| Example 3 | 64.8 | A | A | A |
| Example 4 | 65.4 | A | A | A |
| Example 5 | 62.3 | A | A | A |
| Example 6 | 57.3 | A | A | A |
| Example 7 | 55.0 | A | A | A |
| Comparative | 49.5 | A | B | B |
| Example 2 | | | | |
| Comparative | 46.7 | A | B | B |
| Example 3 | | | | |
| Comparative | 42.4 | A | B | B |
| Example 4 | | | | |
| Comparative | 38.7 | A | B | B |
| Example 5 | | | | |

A: 20 or more
A: 55 or more
A: acceptable
B: less than 20
B: less than 55
B: unacceptable

As shown in Table 1, in Comparative Example 1 (YAP content: 0 vol %), since the YAG phosphor and AlN are simply mixed and sintered, crystal defects of AlN are generated or oxynitride-based impurities such as AlON are generated, and thus the thermal conductivity is as low as 14.3 and the external quantum yield is as low as 46.8%. The number of voids contained in the phosphor is as many as 16.

On the other hand, in Example 1 (YAP amount: 0.1 vol %), Example 2 (YAP amount: 0.3 vol %), Example 3 (YAP amount: 0.7 vol %), Example 4 (YAP amount: 1.1 vol %), Example 5 (YAP amount: 1.9 vol %), Example 6 (YAP amount: 4.6 vol %), and Example 7 (YAP amount: 7.0 vol %), it was confirmed that the numbers of voids were nine or less, and the thermal conductivities were as high as 40.9, 40.7, 46.1, 41.4, 59.2, 43.0, 40.1 and the external quantum yields were as high as 65.6%, 64.9%, 64.8%, 65.4%, 62.3%, 57.3%, and 55.0%, respectively.

That is, it was confirmed that when the YAP amounts were more than 0 vol % and 7.0 vol % or less as in Examples 1 to 7, the thermal conductivities were 20 or more and the external quantum yields were 55% or more.

On the other hand, in Comparative Example 2 (YAP amount: 7.2 vol %), Comparative Example 3 (YAP amount: 8.0 vol %), Comparative Example 4 (YAP amount: 9.1 vol %), and Comparative Example 5 (YAP amount: 10.0 vol %), the numbers of voids were nine or less and the sufficient thermal conductivities of 36.7, 38.0, 31.6, and 30.8 were achieved, however, the external quantum yields were 49.5%, 46.7%, 42.4%, and 38.7% and the fluorescence conversion efficiency was not sufficient.

That is, it was confirmed that when the YAP amounts were higher than 7.0 vol % as in Comparative Examples 2 to 5, the external quantum yields were reduced to less than 55%, and the fluorescence emission efficiency was decreased.

Based on the above results, according to the phosphors in Examples 1 to 7, it is confirmed that the thermal conductivity and the quantum yield are enhanced in a balanced manner by setting of the YAP amount to more than 0 vol % and 7.0 vol % or less to enhance the fluorescence emission efficiency, and thereby, bright fluorescence can be generated.

What is claimed is:

1. A phosphor comprising a phosphor body including:
a phosphor phase formed of A₃B₅O₁₂:Ce having a garnet structure;
a matrix phase having a refractive index higher than a refractive index of the phosphor phase; and
a crystal phase formed of YAlO₃ having a perovskite structure, wherein
a content of the crystal phase is more than 0 vol % and is equal to or less than 7.0 vol % in a volume ratio with respect to the phosphor body,
A is at least one selected from a group including Lu, Gd, Tb, Ga, and Y, and B is Al.

2. The phosphor according to claim 1, wherein
A is Y.

3. The phosphor according to claim 1, wherein
the matrix phase is AlN.

4. The phosphor according to claim 3, wherein
the phosphor body further includes another phosphor phase formed of AlN:Ce.

5. The phosphor according to claim 1, wherein a number of voids of 1.0 μm or more contained within an area of 400 μm² in a cross-sectional view of the phosphor body is equal to or less than nine.

6. The phosphor according to claim 1, wherein
the phosphor body contains a by-product different from the phosphor phase, the matrix phase, and the crystal phase, and
a content of the by-product is less than 1.0 vol % in the volume ratio with respect to the phosphor body.

7. The phosphor according to claim 1, wherein
an emission peak wavelength of the phosphor body is less than 610 nm.

8. A wavelength conversion device comprising:
a substrate;
the phosphor according to claim 1 provided on the substrate and configured to convert an incident excitation light into fluorescence; and
a reflection layer provided at an opposite side to a light incident side of the phosphor.

9. A wavelength conversion device comprising:
a substrate;
the phosphor according to claim 1 provided on the substrate and configured to convert an incident excitation light into fluorescence; and
an optical layer provided at a light incident side of the phosphor, and configured to transmit the excitation light and reflect the fluorescence.

10. An illumination device comprising:
a light source emitting the excitation light; and
the wavelength conversion device according to claim 8, on which the excitation light is incident.

11. An illumination device comprising:
a light source emitting the excitation light; and
the wavelength conversion device according to claim 9, on which the excitation light is incident.

12. A projector comprising:
the illumination device according to claim 10;
a light modulator modulating a light emitted from the illumination device; and
a projection optical device projecting the light modulated by the light modulator.

13. A projector comprising:
the illumination device according to claim 11;
a light modulator modulating a light emitted from the illumination device; and
a projection optical device projecting the light modulated by the light modulator.
